(19) United States
(12) Patent Application Publication
(10) Pub. No.: US 2023/0086448 A1
(43) Pub. Date: Mar. 23, 2023

(54) LIQUID COOLING PLATE SUITABLE FOR LIQUID COOLING HEAT DISSIPATION OF ELECTRONIC DEVICE, AND HEAT DISSIPATION UNIT

(71) Applicant: SHENZHEN MICROBT ELECTRONICS TECHNOLOGY CO., LTD., SHENZHEN, GUANGDONG (CN)

(72) Inventors: Qian CHEN, SHENZHEN, GUANGDONG (CN); Fangyu LIU, SHENZHEN, GUANGDONG (CN); Yang GAO, SHENZHEN, GUANGDONG (CN); Yuefeng WU, SHENZHEN, GUANGDONG (CN); Hongyan NING, SHENZHEN, GUANGDONG (CN)

(73) Assignee: SHENZHEN MICROBT ELECTRONICS TECHNOLOGY CO., LTD., SHENZHEN, GUANGDONG (CN)

(21) Appl. No.: 17/801,302

(22) PCT Filed: Apr. 25, 2021
(86) PCT No.: PCT/CN2021/089655

§ 371 Date: Aug. 22, 2022

(30) Foreign Application Priority Data
May 12, 2020 (CN) 202020778277.8

(51) Int. Cl. G06F 1/20; H05K 7/20; G06F 1/18

(52) U.S. Cl. CPC G06F 1/20; H05K 7/20; G06F 1/183

(57) ABSTRACT

Disclosed are a liquid cooling plate suitable for liquid cooling heat dissipation of an electronic device and a heat dissipation unit. The liquid cooling plate includes a liquid cooling plate body and at least one heat dissipation flow channel, wherein the liquid cooling plate body is provided with a first heat dissipation surface and a second heat dissipation surface that are arranged in parallel, the first heat dissipation surface being planar, a plurality of heat dissipation bosses being arranged on the second heat dissipation surface, and heat dissipation flow channels extending along the heat dissipation bosses are provided inside the liquid cooling plate body at positions corresponding to the at least one of the heat dissipation bosses between the first heat dissipation surface and the second heat dissipation surface, the plurality of heat dissipation flow channels being connected to form a cooling liquid flow path having an inlet and an outlet.

### CROSS-REFERENCE TO RELATED APPLICATIONS

The present application claims the priority to Chinese Patent Application No. 202020778277.8, filed to the China National Intellectual Property Administration on May 12, 2020 and entitled “liquid cooling plate suitable for liquid cooling heat dissipation of electronic device and heat dissipation unit having it”, which is incorporated in its entirety herein by reference.

### TECHNICAL FIELD

The present application relates to the technical field of liquid cooling heat dissipation of electronic devices, and in particular to a liquid cooling plate suitable for liquid cooling heat dissipation of an electronic device and a heat dissipation unit.

### BACKGROUND

With the development of computing technology, the requirements for the operational performance of the electronic device are becoming higher and higher, which leads to the increase in power consumption and density of components such as chips in the electronic device. In order to ensure the best working state of the electronic device, it is necessary to dissipate the heat of the electronic device. However, at present, the traditional air-cooled heat dissipation (for example, the fan used for heat dissipation) cannot satisfy the above heat dissipation requirements.

In the prior art, a liquid cooling plate can be additionally mounted on the surface of the electronic device, so as to ensure the timely heat dissipation of the electronic device.

However, in the solution above, due to structural limitation of the liquid cooling plate, the liquid cooling plate is usually additionally mounted on the side of the electronic device that is provided with heating components, and a fan is still used for heat dissipation for the other side of the electronic device. That is, the existing liquid cooling plate only solves parts of heat loads of the electronic device, and does not completely remove the fan, resulting in poor heat dissipation effect and inconvenience in mounting and using.

### SUMMARY

Embodiments of the present application provide a liquid cooling plate suitable for liquid cooling heat dissipation of an electronic device and a heat dissipation unit.

Embodiments of the present application provides a liquid cooling plate suitable for liquid cooling heat dissipation of an electronic device, and the liquid cooling plate includes a liquid cooling plate body and at least one heat dissipation flow channel, wherein

The liquid cooling plate body is provided with a first heat dissipation surface and a second heat dissipation surface that are arranged in parallel, wherein the first heat dissipation surface is a plane, and a plurality of heat dissipation bosses are arranged on the second heat dissipation surface; and

Heat dissipation flow channels extending along the heat dissipation bosses are provided inside the liquid cooling plate body at positions corresponding to the at least one of the heat dissipation bosses between the first heat dissipation surface and the second heat dissipation surface, wherein the plurality of heat dissipation flow channels are connected to form a cooling liquid flow path provided with an inlet and an outlet.

An embodiment of the present application further discloses a heat dissipation unit, and the heat dissipation unit includes at least two liquid cooling plates, wherein the liquid cooling plates are the liquid cooling plate in the above embodiment;

wherein the first heat dissipation surfaces of the at least two liquid cooling plates are in butt joint with a planer surface of a first electronic device, and cooling liquid flow paths of the at least two liquid cooling plates are arranged in parallel, so as to enable liquid cooling heat dissipation of the first electronic device; alternatively,

The at least two liquid cooling plates are arranged in a stacked manner with a second electronic device arranged between the adjacent liquid cooling plates, wherein the first heat dissipation surface of one of the adjacent liquid cooling plates is in butt joint with a first surface of the second electronic device that is a plane, a second heat dissipation surface of the other one of the adjacent liquid cooling plates is in butt joint with a second surface of the second electronic device on which heating units are arranged, and heat dissipation bosses on the second heat dissipation surface abut against the heating units, wherein the cooling liquid flow paths of the at least two liquid cooling plates are arranged in parallel, so as to enable liquid cooling heat dissipation of the second electronic device.

One or more technical solutions provided in the embodiments of the present application at least have the following technical effects or advantages:

In an embodiment of the present application, the liquid cooling plate includes a liquid cooling plate body, wherein the liquid cooling plate body is provided with a planar first heat dissipation surface and a second heat dissipation surface having a plurality of heat dissipation bosses, heat dissipation flow channels are arranged between the first heat dissipation surface and the second heat dissipation surface corresponding to positions of the heat dissipation bosses, the heat dissipation flow channels extend along the heat dissipation bosses, and the plurality of heat dissipation flow channels are connected to form a cooling liquid flow path provided with an inlet and an outlet for cooling liquid to circulate. In this way, the cooling liquid flows into the inlet of the cooling liquid flow path and flows out of the outlet, so as to enable liquid cooling heat dissipation of the electronic device.

In an embodiment of the present application, when the electronic device is the first electronic device such as a power box, etc., the first heat dissipation surface of the liquid cooling plate is used for being in butt joint with a plane of the power box, so as to dissipate heat. In another embodiment of the present application, when the electronic device is a hashboard such as a data processing device, the plurality of liquid cooling plates are stacked and the second heat dissipation surfaces of the plurality of liquid cooling plates face the same direction, and then hashboards are arranged between the adjacent liquid cooling plates, and the surfaces of the hashboards provided with heating units are in butt joint with the second heat dissipation surfaces. In this way, by means of stacked and sandwiched arrangement of the liquid cooling plates and the hashboards, the plurality of liquid cooling plates can achieve complete liquid cooling heat dissipation of the first surfaces and the second surfaces of the hashboards. By using the liquid cooling plate in an embodiment of the present application, it is unnecessary to use a fan, and the heat dissipation effect is excellent so that heat dissipation loads of the above two electronic devices can be completely borne, with convenient using and mounting.

### BRIEF DESCRIPTION OF DRAWINGS

FIG. 1 is a structural schematic diagram of a liquid cooling plate in an embodiment of the present application.

FIG. 2 is a schematic diagram of a mounting structure of a first sealing plate, a second sealing plate and a heat dissipation body in an embodiment of the present application.

FIG. 3 is a structural schematic diagram of heat dissipation flow channels in an embodiment of the present application.

FIG. 4 is a schematic diagram of an installation structure of a first heat dissipation surface and a second electronic device in an embodiment of the present application.

FIG. 5 is a schematic diagram of a mounting structure of a liquid cooling plate and a second electronic device in an embodiment of the present application.

FIG. 6 is a schematic diagram of a mounting structure of a liquid cooling plate and a first electronic device in an embodiment of the present application.

FIG. 7 is a schematic diagram of a mounting structure of a plurality of liquid cooling plates and a plurality of second electronic devices in an embodiment of the present application.

FIG. 8 is a structural schematic diagram of the parallel connection of heat dissipation flow channels in an embodiment of the present application.

### REFERENCE NUMERALS

10—Liquid cooling plate,

11—First sealing plate, 111—First through hole, 112—Second through hole,

12—Second sealing plate,

13—Heat dissipation body,

131—First heat dissipation surface, 1311—First mounting hole, 1312—Mounting outer edge, 1313—Second mounting hole,

132—Second heat dissipation surface, 1321—Heat dissipation boss, 1322—Abutment boss,

133—Heat dissipation flow channel, 1331—Corrugated protrusion,

134—Supporting wall,

135—Gap,

136—Hollow cavity,

14—Butt joint pipe,

15—First electronic device,

16—Second electronic device, 161—Substrate unit, 162—Heating unit, and

17—Screw.

### DETAILED DESCRIPTION OF THE EMBODIMENTS

In order to better understand the above technical solution, the above technical solution will be described in detail below in combination with the drawings and the specific embodiments of the description.

With the development of computing technology, particularly with the development of a virtual currency technology, the demand for a data processing device for acquiring virtual currency is increasing constantly, and requirements for the size of the data processing device and the performance of the hash rate of a chip are higher and higher, resulting in improvement of power consumption and density of the chips. Meanwhile, in order to maintain the chips in an optimal working state so as to develop the performance of the data processing device to the fullest, it is necessary to dissipate the heat of electronic devices such as a hashboard and a power box of the data processing device. However, a traditional data processing device depending on air cooling heat dissipation results to a severe working environment, large air cooling heat dissipation noise and a large temperature difference of the chips at the air inlet and outlet positions of the hashboard. In an embodiment of the present application, the data processing device for acquiring virtual currency can be a computer for acquiring virtual currency, which includes at least one hashboard, each of the hashboards having a heating unit providing hash rate which refers to a measurement unit of the network processing capacity of the virtual currency, i.e. speed of output of the computing hash function.

At present, for example, a liquid cooling plate can be used for enabling liquid cooling heat dissipation of a hashboard. However, due to structural limitations, the existing liquid cooling plate only processes parts of the heat loads of the data processing device, and does not completely remove a fan, resulting in poor heat dissipation effect and inconvenience in mounting and using. Therefore, it is necessary to provide a cold plate type liquid cooling heat dissipation structure capable of solving all heat loads of the data processing device.

An embodiment of the present application provides a liquid cooling plate suitable for liquid cooling heat dissipation of an electronic device. The liquid cooling plate 10 includes a liquid cooling plate body and at least one heat dissipation flow channel 133, wherein the liquid cooling plate body has a first heat dissipation surface 131 and a second heat dissipation surface 132 that are arranged in parallel, the first heat dissipation surface 131 is a plane, and a plurality of heat dissipation bosses 1321 are arranged on the second heat dissipation surface 132; heat dissipation flow channels 133 extending along the heat dissipation bosses 1321 are provided inside the liquid cooling plate body at positions corresponding to the at least one of the heat dissipation bosses 1321 between the first heat dissipation surface 131 and the second heat dissipation surface 132, wherein the plurality of heat dissipation flow channels 133 are connected to form a cooling liquid flow path provided with an inlet and an outlet. In an embodiment of the present application, one heat dissipation flow channel can correspond to one heat dissipation boss and can also correspond to two or more heat dissipation bosses, and the inlet and the outlet of the cooling liquid flow path are connected with a cooling liquid external circulation heat dissipation system.

In an embodiment of the present application, the first heat dissipation surface 131 is used for being in butt joint with a planar surface of a first electronic device 15, and a cooling liquid flows into the inlet of the cooling liquid flow path and flows out of the outlet so as to enable liquid cooling heat dissipation of the first electronic device 15. In specific embodiments, the first electronic device can be a power box of a data processing device, and first heat dissipation surface on the liquid cooling plate body that is planar can be in butt joint with a surface of the power box so that the liquid cooling plate can be used for dissipating heat for the power box.

In another embodiment of the present application, the first heat dissipation surface 131 is used for being in butt joint with a first surface of a second electronic device 16 that is planar, the second heat dissipation surface 132 is used for being in butt joint with a second surface of the second electronic device 16 on which heating units 162 are arranged, and the heat dissipation bosses 1321 are used for abutting against the heating units 162, each of the heat dissipation bosses corresponding to at least one of the heating units in a section width perpendicular to a flow direction of the cooling liquid, the cooling liquid flowing into the inlet of the cooling liquid flow path and flowing out of the outlet so as to enable liquid cooling heat dissipation of the second electronic device. In specific embodiments, the second electronic device can be a hashboard of the data processing device. For example, the first heat dissipation surface on the liquid cooling plate body that is planar can be in butt joint with a first surface (i.e., a back surface of a hashboard 1, which is planar) of the hashboard 1, and the second heat dissipation surface on which the plurality of heat dissipation bosses are arranged is in butt joint with a second surface (i.e., a front surface of a hashboard 2) of the hashboard 2 provided with heating units, so that the liquid cooling plate is used for dissipating heat for the plurality of hashboards. The hashboard 1 and the hashboard 2 can also be referred to as a hashboard group of the data processing device. One liquid cooling plate can only dissipate heat for the back surface of the hashboard 1 and the front surface of the hashboard 2, and therefore, the front surface of the hashboard 1 and the back surface of the hashboard 2 can be in butt joint with other liquid cooling plates respectively for heat dissipation. In an embodiment of the present application, the heating units can be computing chips.

In an embodiment of the present application, if the power box and the hashboard (group) of the data processing device both use the liquid cooling plates provided in the present application for heat dissipation, the liquid cooling plates for dissipating heat for the power box and the liquid cooling plates used for dissipating heat for the hashboard (group) can be independently arranged. In other embodiments of the present application, only the hashboard (group) of the data processing device may use the liquid cooling plates provided in the present application for heat dissipation, and the power box may use other liquid cooling boards having planar contact surfaces for heat dissipation.

In an embodiment of the present application, the power box, the hashboard and the liquid cooling plate provided in the present application can form a sandwich structure. For example, a planar surface of the power box is in butt joint with the first heat dissipation surface (which is planar) of the liquid cooling plate, and the second heat dissipation surface (on which a plurality of heat dissipation bosses are arranged) of the liquid cooling plate is in butt joint with the front surface (which is provided with chips) of the hashboard, such that the power box and the hashboard both dissipate heat by means of the liquid cooling plate. The power box, the hashboard group, and the liquid cooling plate provided in the present application can also form a sandwich structure. For example, when the power box has 2 planar surfaces, the planar surface 1 of the power box is in butt joint with the first heat dissipation surface (which is planar) of the liquid cooling plate 1, the second heat dissipation surface (on which a plurality of heat dissipation bosses are arranged) of the liquid cooling plate 1 is in butt joint with the front surface (which is provided with chips) of the hashboard 1, the planar surface 2 of the power box is in butt joint with the first heat dissipation surface (which is planar) of the liquid cooling plate 2, the second heat dissipation surface (on which a plurality of heat dissipation bosses are arranged) of the liquid cooling plate 2 is in butt joint with the front surface (which is provided with chips) of the hashboard 2, and furthermore, the back surface (which is planar and has no chip on it) of the hashboard 1 can also be in butt joint with the first heat dissipation surface of the liquid cooling plate 3, and the back surface (which is planar and has no chip) of the hashboard 2 can also be in butt joint with the first heat dissipation surface of the liquid cooling plate 4, and so on, until the power box and all the hashboards dissipate heat by means of the liquid cooling plates, wherein liquid cooling plates 3, 4 may not be limited to the liquid cooling plate in the present application. For example, if the hashboard group of the data processing device includes at least two hashboards, the surface of the power box is in butt joint with the first heat dissipation surface (which is planar) of the liquid cooling plate 1, the second heat dissipation surface (on which a plurality of heat dissipation bosses are arranged) of the liquid cooling plate 1 is in butt joint with the front surface (which is provided with chips) of the hashboard 1, the back surface (which is planar and has no chip on it) of the hashboard 1 is in butt joint with the first heat dissipation surface of the liquid cooling plate 2, and the second heat dissipation surface of the liquid cooling plate 2 is in butt joint with the front surface of the hashboard 2, and so on, until the power box and all the hashboards dissipate heat by means of the liquid cooling plates.

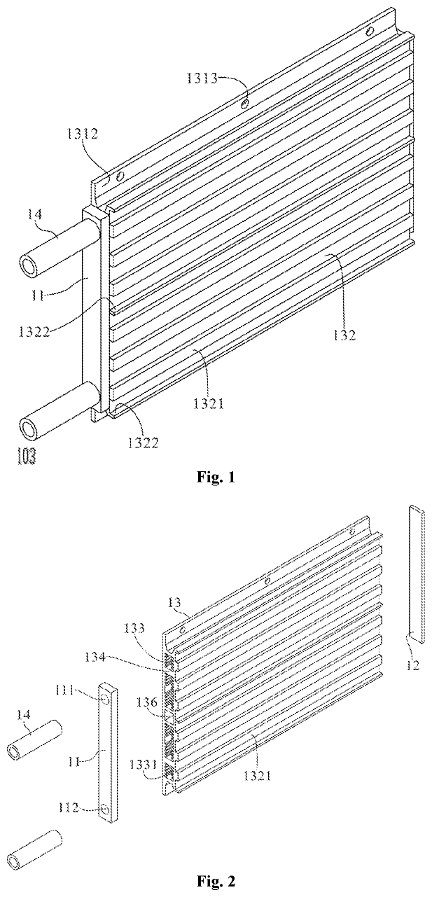

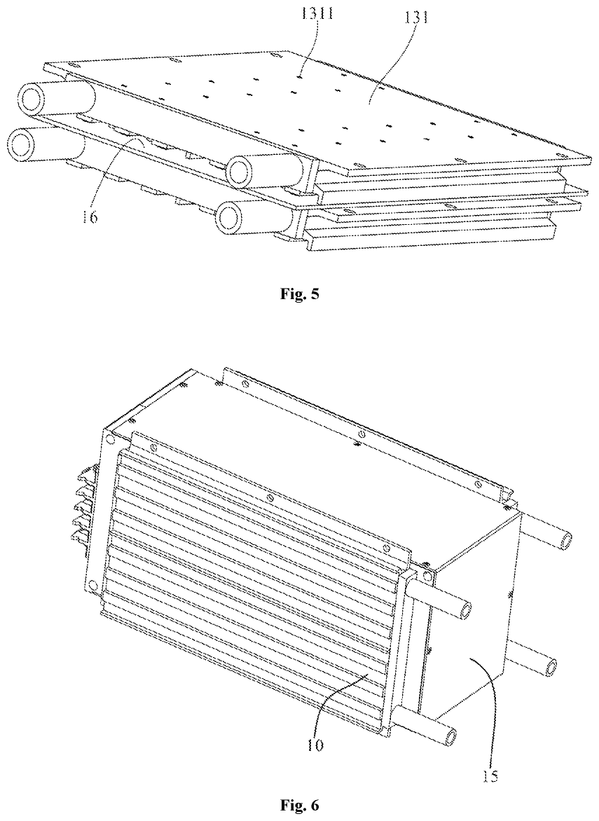

Specifically, in combination with FIGS. 1, 2 and 5, the liquid cooling plate body is in, for example, a flat plate shape, the first heat dissipation surface and the second heat dissipation surface of the liquid cooling plate body are arranged in parallel, the second heat dissipation surface is provided with the plurality of heat dissipation bosses, the first heat dissipation surface is planar, and then the liquid cooling plate body is internally provided with a cooling liquid flow path formed by the plurality of heat dissipation flow channels in connection between the first heat dissipation surface and the second heat dissipation surface, the cooling liquid flow path having an inlet and an outlet that are connected with the cooling liquid external circulation heat dissipation system. In this way, the cooling liquid enters from the inlet, then flows through the cooling liquid flow path inside the liquid cooling plate body, and then flows out from the outlet, and therefore the two heat dissipation surfaces of the liquid cooling plate body can achieve heat dissipation effect.

For example, in combination with FIG. 6, the liquid cooling plate can be suitable for the first electronic device 15, which has at least one planar surface and, for example, is the power box of the data processing device, and then the liquid cooling plate is arranged on the side wall (which is planar) of the power box, and the first heat dissipation surface 131 of the liquid cooling plate is mounted on the side wall of the power box. When a plurality of liquid cooling plates are mounted, the cooling liquid flow paths of the plurality of liquid cooling plates can be arranged in parallel. In this way, the liquid cooling plates may enable liquid cooling heat dissipation of the first electronic device and uniformly dissipate heat. According to actual needs, the liquid cooling plates can be mounted on a plurality of planes of the first electronic device.

For example, in combination with FIGS. 4, 5 and 7, the liquid cooling plate can be suitable for the second electronic device 16, which, for example, is the hashboard of the data processing device. The hashboard includes a substrate unit 161, wherein a first surface of the substrate unit is a plane, and a second surface of the substrate unit is provided with heating units 162, for example, computing chips arranged in an array. Then sandwich the two liquid cooling plates together with the second electronic device, wherein the first heat dissipation surface of the first liquid cooling plate is in butt joint with the first surface of the substrate unit, the second heat dissipation surface of the second liquid cooling plate is in butt joint with the second surface of the substrate unit, and the heat dissipation bosses of the second heat dissipation surface abut against the heating units. In this way, the two liquid cooling plates can dissipate heat from two surfaces of the second electronic device and can completely satisfy heat dissipation requirements of the second electronic device without using a fan, with uniform heat dissipation.

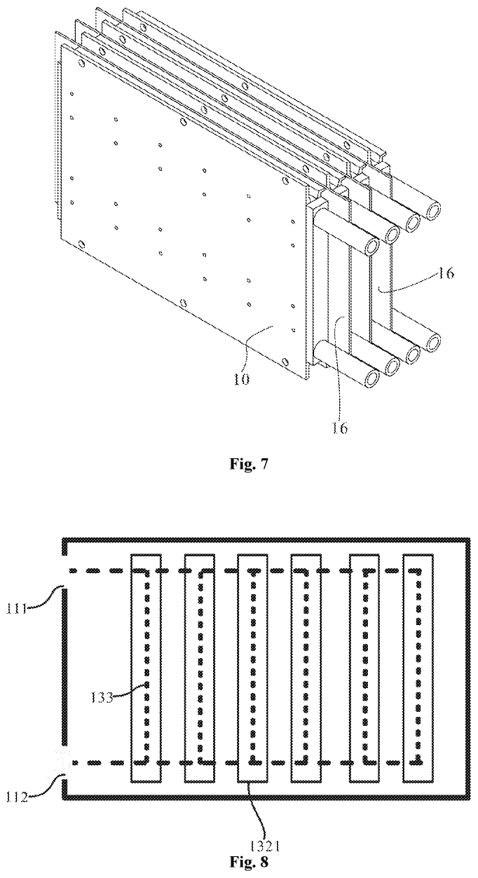

In addition, in an embodiment of the present application, the plurality of hashboards are usually arranged in a stacked manner, and in that case, in combination with FIG. 7, the plurality of liquid cooling plates and the plurality of hashboards can be arranged in a stacked and sandwiched manner, and the cooling liquid flow paths of the plurality of liquid cooling plates can be arranged in parallel, that is, liquid cooling heat dissipation can be carried out simultaneously for two hashboards on both sides by means of one liquid cooling plate, or liquid cooling heat dissipation can be carried out for one hashboard by means of the two liquid cooling plates on both sides, such that heat dissipation efficiency is improved, and the plurality of liquid cooling plates can bear all heat loads of the hashboard, without the need to use a fan.

On the basis of the above embodiments, it can be seen that first heat dissipation surface that is planar and the second heat dissipation surface provided with heat dissipation bosses are arranged on the liquid cooling plate, such that the liquid cooling plate may satisfy the heat dissipation requirements of the hashboard and/or a power supply apparatus of the data processing device, and when the data processing device has a plurality of hashboards, the plurality of liquid cooling plates and the plurality of hashboards and/or the power box can be arranged in a stacked and sandwich manner, such that liquid cooling heat dissipation can be carried out from two surfaces of the hashboards and/or the power box and the heat dissipation requirements of the hashboards can be satisfied without using a fan, with uniform heat dissipation.

That is, the liquid cooling plate in an embodiment of the present application can be suitable for liquid cooling heat dissipation of two electronic devices, i.e., the power and the hashboard, and can satisfy the heat dissipation requirements of the two electronic devices, without need to mount a fan.

In an embodiment of the present application, the liquid cooling plate includes the liquid cooling plate body having a first heat dissipation surface that is planar and a second heat dissipation surface provided with a plurality of heat dissipation bosses, and heat dissipation flow channels extending along the heat dissipation bosses and corresponding to positions of the heat dissipation bosses are arranged between the first heat dissipation surface and the second heat dissipation surface, and the plurality of heat dissipation flow channels are connected to form a cooling liquid flow path having an inlet and an outlet, such that the cooling liquid flows into the inlet of the cooling liquid flow path and flows out of the outlet, so as to enable liquid cooling heat dissipation of the electronic device.

In an embodiment of the present application, when the electronic device is the first electronic device such as the power box, the first heat dissipation surface of the liquid cooling plate is used for being in butt joint with the plane of the power box so as to dissipate heat. In another embodiment of the present application, when the electronic device is, for example, the hashboard of a data processing device, the plurality of liquid cooling plates are stacked and the second heat dissipation surfaces of the plurality of liquid cooling plates face the same direction, and then hashboards are arranged between the adjacent liquid cooling plates, wherein the surfaces of the hashboards provided with heating units are in butt joint with the second heat dissipation surfaces. For example, when the electronic device is a hashboard of which heating components are arranged on one surface of the substrate unit and the other surface of the substrate unit is planar, the first heat dissipation surface of one of the liquid cooling plates is used for being in butt joint with the plane of the substrate unit, and the second heat dissipation surface of the other one of the liquid cooling plates is used for being in butt joint with one surface of the substrate unit having the heating units, wherein the heat dissipation bosses of the second heat dissipation surface abut against the heating units so as to dissipate heat. In this way, by means of stacked and sandwiched arrangement of the liquid cooling plates and the hashboards, the plurality of liquid cooling plates may achieve complete liquid cooling heat dissipation of the first surfaces and the second surfaces of the hashboards. By using the liquid cooling plate in an embodiment of the present application, it is unnecessary to use a fan, and the heat dissipation effect is excellent so that heat dissipation loads of the above two electronic devices can be completely borne, with convenient using and mounting.

In an embodiment of the present application, an area of the first heat dissipation surface or the second heat dissipation surface of the above-mentioned liquid cooling plate can be determined according to actual needs; moreover, a thickness of the liquid cooling plate, i.e., a thickness between the two heat dissipation surfaces, can be determined according to the diameter of the actually needed heat dissipation flow channels.

In an embodiment of the present application, the heat dissipation flow channels are determined according to the number and positions of the heat dissipation bosses. For example, several heat dissipation bosses are arranged in parallel on the second heat dissipation surface, wherein the number of the heat dissipation flow channels is the same as that of the heat dissipation bosses, that is, one heat dissipation flow channel corresponding to one heat dissipation boss, and positions of the heat dissipation flow channels correspond to positions of the heat dissipation bosses between the first heat dissipation surface and the second heat dissipation surface; for another example, one heat dissipation flow channel can correspond to two or more heat dissipation bosses, that is, the number of the heat dissipation flow channels can be less than the number of the heat dissipation bosses; alternatively, in other words, one heat dissipation flow channel can correspond to at least one heat dissipation boss. In addition, several heat dissipation flow channels are connected to form a cooling liquid flow path. In an embodiment of the present application, the cooling liquid flow path has two ports, i.e., the inlet and the outlet, so as to circulate the cooling liquid.

In the above embodiment, intervals of the heat dissipation bosses are determined according to an array arrangement condition of the heating units on the second electronic device, for example, according to an array arrangement condition of the chips on the hashboard. The intervals of the heat dissipation flow channels may correspond to intervals of the heat dissipation bosses. A width of the heat dissipation bosses should ensure coverage of the heating units. For example, the width of the heat dissipation bosses is slightly greater than the width of the heating units. In addition, one of the heat dissipation bosses can also correspond to the width of the plurality of heating units, that is, at least one heating unit can be arranged in a section width perpendicular to a flow direction of the cooling liquid.

In an embodiment of the present application, the heat dissipation bosses correspond to the heating units in position, and other electronic elements are avoided by means of gaps between the adjacent heat dissipation bosses; the center positions of the heat dissipation flow channels correspond to center positions of the heating units so as to ensure that heat of the heating units can be discharged in time.

In a possible embodiment, a plurality of heat dissipation flow channels are connected in series to form a cooling liquid flow path.

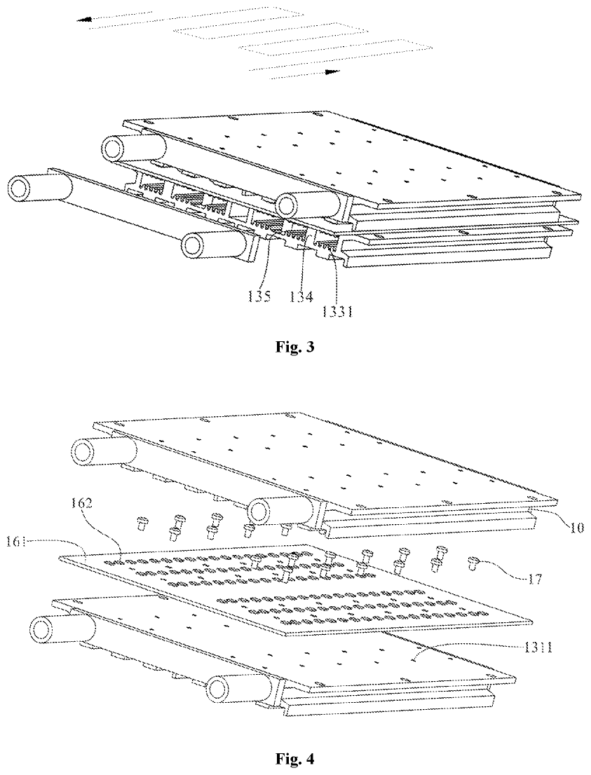

Specifically, in combination with FIG. 3, for example, the plurality of heat dissipation flow channels are connected in series to form a S-shaped cooling liquid flow path, an arrow direction in FIG. 3 indicating the flow direction of the cooling liquid along the cooling liquid flow path. In this way, it can be ensured that the cooling liquid flow path connects each of the heat dissipation flow channels in series, thereby ensuring uniform heat dissipation.

In a possible embodiment, the liquid cooling plate body also has a first side wall and a second side wall that are oppositely arranged between the first heat dissipation surface and the second heat dissipation surface; wherein the inlet and the outlet of the cooling liquid flow path are provided on the first side wall.

Specifically, in combination with FIG. 2, in the embodiment, the inlet and the outlet of the cooling liquid flow path are provided on the same side wall, i.e., the first side wall, which is located between the first heat dissipation surface and the second heat dissipation surface. Thus, when the inlet and the outlet are externally connected to pipelines, it can be ensured that the external pipelines of the cooling liquid are located on the same side of the liquid cooling plate, and then interfaces such as a power supply or a signal line can be arranged on the other side (the second side wall) of the liquid cooling plate so as to achieve liquid-power separation, thereby improving use convenience, safety and reliability.

In a possible embodiment, the liquid cooling plate body includes a heat dissipation body 13 and a first sealing plate 11 and a second sealing plate 12 that are mounted on the heat dissipation body 13; wherein the heat dissipation body 13 has the above-mentioned first heat dissipation surface 131 and the second heat dissipation surface 132, the heat dissipation flow channels 133 are arranged inside the heat dissipation body 13, penetrating two ends of the heat dissipation body 13; the first sealing plate 11 and the second sealing plate 12 are mounted at two ends of the heat dissipation body 13 respectively, so as to seal the heat dissipation flow channels 133 by the first sealing plate 11 and the second sealing plate 12 and form the first side wall and the second side wall by the first sealing plate 11 and the second sealing plate 12 respectively; wherein a first through hole 111 and a second through hole 112 are each provided on the first sealing plate 11, and the first through hole 111 and the second through hole 112 form the inlet and the outlet of the cooling liquid respectively.

Specifically, in combination with FIG. 2, the liquid cooling plate body includes the heat dissipation body, the first sealing plate and the second sealing plate, wherein the heat dissipation body has the above-mentioned first heat dissipation surface and the second heat dissipation surface, a plurality of heat dissipation flow channels are arranged inside the heat dissipation body penetrating the heat dissipation body, and then the first sealing plate and the second sealing plate are mounted at two ends of the heat dissipation body respectively to seal the heat dissipation flow channels. In this way, the first sealing plate forms the first side wall and the second sealing plate forms the second side wall at positions corresponding to the heat dissipation flow channels on two sides, wherein the first through hole and the second through hole are each provided on the first sealing plate, such that the first through hole and the second through hole form the inlet and the outlet of the cooling liquid flow path respectively.

In the embodiment, forming the liquid cooling plate body by mounting and splicing three mounting members, wherein the first sealing plate and the second sealing plate can be fixedly mounted on the heat dissipation body in a welded or bonded manner, the heat dissipation body provided with through heat dissipation flow channels, which is convenient to treat and easy to implement.

For the composition of the above cooling liquid flow path, in a possible embodiment, adjacent heat dissipation flow channels 133 are separated by a supporting wall 134, on which a gap 135 is provided; moreover, the gaps 135 of the adjacent supporting walls 134 are close to the first sealing plate 11 and the second sealing plate 12 respectively, so as to connect the plurality of heat dissipation flow channels 133 in series to form a cooling liquid flow path.

In combination with FIGS. 2 and 3, the supporting walls are arranged between the first heat dissipation surface and the second heat dissipation surface, and the heat dissipation flow channels are formed between the adjacent supporting walls, and a gap is provided at one end of the supporting wall, and the cooling liquid may pass through the gap; the gaps of the adjacent supporting walls are close to the first sealing plate and the second sealing plate respectively, that is, for example, the gap of the first supporting wall is located on the side of the first sealing plate, and the gap of the second supporting wall adjacent to the first supporting wall is located on the side of the second sealing plate, and so on. In this way, the plurality of heat dissipation flow channels can be connected in series to form a cooling liquid flow path; then the heat dissipation flow channels on both sides penetrate the first sealing plate to form the first through hole and the second through hole, respectively.

In the embodiment, by means of a simple design of the gaps and series connection of the plurality of heat dissipation flow channels, uniform heat dissipation can be achieved. Moreover, the gaps on the heat dissipation body are convenient to treat and easy to implement. In addition, the size of the gaps should be determined according to the flow amount and speed of the cooling liquid that actually needed.

In a possible embodiment, the first heat dissipation surface 131 is provided with a plurality of first mounting holes 1311 that avoid the heat dissipation flow channels 133; a mounting outer edge 1312 protrudes from the first heat dissipation surface 131, and the mounting outer edge 1312 is provided with second mounting holes 1313.

With reference to FIGS. 1 and 4, in order to enable the liquid cooling plate to be tightly attached to the first electronic device or the second electronic device for heat dissipation, the plurality of first mounting holes are provided on the first heat dissipation surface, and screws 17 penetrate a side wall of the first electronic device or the substrate unit of the second electronic device and are fixed in the first mounting holes to achieve fixed mounting. In an embodiment of the present application, the first mounting holes should avoid positions of the heat dissipation flow channels of the liquid cooling plate.

In addition, the mounting outer edge protrudes from the first heat dissipation surface, and the second mounting holes are provided on the mounting outer edge. In combination with FIGS. 1, 6 and 7, screw rods (not shown in the figures) can be used to penetrate the second mounting holes so as to mount the plurality of liquid cooling plates in a stacked manner or mount the liquid cooling plates fixedly on two side walls of the power box.

In an embodiment of the present application, for example, when the two liquid cooling plates are mounted on the two side walls of the power box, first use the screw rods to penetrate the second mounting holes so as to sandwich the power box between the two liquid cooling plates, and then use the screws to locate and mount in the first mounting holes from an interior of the power box according to actual needs.

In a possible embodiment, the second heat dissipation surface is further provided with abutment bosses 1322 higher than the heat dissipation bosses 1321 so that the abutment bosses 1322 abut against the second surface of the second electronic device 16 while the heat dissipation bosses 1321 abutting against the heating units 162; the abutment bosses 1322 are arranged at two ends of the second heat dissipation surface 132, and/or, the abutment bosses 1322 are arranged between the adjacent heat dissipation bosses 1321.

With reference to FIG. 2, the abutment bosses are further arranged on the second heat dissipation surface, which are used for abutting against the substrate unit of the second electronic device. In an embodiment of the present application, the heating units having a certain height are arranged on the substrate unit. The heat dissipation bosses are used for abutting against the heating units, and then the abutment bosses are used for abutting against the substrate unit, and therefore a height of the abutment bosses is larger than that of the heat dissipation bosses and is specifically determined according to the height of the heating units. That is, a height difference between the abutment bosses and the heat dissipation bosses should be the height of the heating units, and in that case, when the abutment bosses abut against the substrate unit, the heat dissipation bosses just abut against the heating units, so as to ensure that the heat dissipation bosses are fully contacted with the heating units to facilitate heat dissipation and ensure that the heating units are not damaged by extrusion of the heat dissipation bosses.

In an embodiment of the present application, with reference to FIG. 2, the abutment bosses can be arranged at two ends of the second heat dissipation surface; in another embodiment of the present application, the abutment bosses can be arranged in the middle of the second heat dissipation surface, that is, the abutment bosses can be located between the adjacent heat dissipation bosses.

In a possible embodiment, the first heat dissipation surface is coated with thermally conductive silicone grease, and surfaces of the heat dissipation bosses are provided with thermally conductive silicone pads.

The thermally conductive silicone grease facilitates the conduction of heat from the side wall of the first electronic device or the substrate unit of the second electronic device to the first heat dissipation surface. On one hand, the thermally conductive silicone pads facilitate the conduction of heat from the heating units to the heat dissipation bosses, and on the other hand, the thermally conductive silicone pads have a buffering effect to prevent the heat dissipation bosses from extruding and damaging the heating units. The thermally conductive silicone grease and the thermally conductive silicone pads facilitate improvement of heat dissipation efficiency and heat dissipation uniformity.

In a possible embodiment, hollow cavities 136 are further provided inside the liquid cooling plate body and located between the adjacent heat dissipation flow channels 133.

With reference to FIG. 2, one or more hollow cavities can be further provided inside the liquid cooling plate body, which are located between the adjacent heat dissipation flow channels, such that the hollow cavities may help to reduce the weight of the liquid cooling plate and reduce cost.

In a possible embodiment, inner walls of the heat dissipation flow channels are provided with flow disturbing structures; the flow disturbing structures include corrugated protrusions 1331 or tooth-shaped protrusions extending along the heat dissipation flow channel, and/or the flow disturbing structures include spiral protrusions extending along the heat dissipation flow channel.

In the embodiment, the flow disturbing structures can be arranged inside the heat dissipation flow channel. The flow disturbing structures may have an effect of convection and heat transfer enhancement on the cooling liquid, that is, the flow disturbing structures increase the flow speed and enhance turbulence intensity, thereby reducing a temperature difference between the cooling liquid and the heating units and ensuring a good heat exchanging effect under the condition that the circulation flow of cooling liquid is small.

With reference to FIG. 2, the flow disturbing structures may use a corrugated protrusion design with a simple processing technology, and the design reduces a circulation interface under the requirement of a certain flow channel width while increasing the heat exchange area. In other embodiments, the flow disturbing structures may use the spiral protrusions extending along the heat dissipation flow channels. In other embodiments, the flow disturbing structures can be further implemented by flow disturbing columns designed inside the heat dissipation flow channels or flow disturbing structural members (such as spiral springs, etc.) filled inside the heat dissipation flow channels.

In a possible embodiment, in combination with FIGS. 1 and 2, the first through hole 111 and the second through hole 112 extend outwards to be provided with butt joint pipes 14 that are used to be connected to the cooling liquid.

In a possible embodiment, the plurality of the heat dissipation flow channels 133 are connected in parallel to form the cooling liquid flow path.

In the embodiment, in combination with FIG. 8, the plurality of heat dissipation flow channels can further be connected in parallel to form the cooling liquid flow path. In this case, the heat dissipation flow channels 133 should be arranged in a direction perpendicular to the first side wall and the second side wall.

In an embodiment of the present application, when the plurality of heat dissipation flow channels are connected in series, the cooling liquid sequentially flows through each of the heat dissipation flow channels, that is, for the heat dissipation flow channels after the first heat dissipation flow channel, the entered cooling liquid has absorbed a certain amount of heat, which influences the heat dissipation in a bad way. In this case, the circulation flow of the cooling liquid can be reduced, and the flow speed of the cooling liquid can be increased. That is, series connection of the heat dissipation flow channels is suitable for the condition of smaller circulation flow of the cooling liquid.

When the plurality of heat dissipation flow channels are connected in parallel, the cooling liquid flows through each of the heat dissipation flow channels at the same time, and there is not such bad influences on the heat dissipation. Therefore, parallel connection of the heat dissipation flow channels is suitable for the condition of larger circulation flow of the cooling liquid.

An embodiment of the present application further provides a heat dissipation unit having liquid cooling plates, and the heat dissipation unit includes at least two liquid cooling plates, wherein the at least two liquid cooling plates are the liquid cooling plate in the above embodiment;

wherein the first heat dissipation surfaces of the at least two liquid cooling plates are in butt joint with a planer surface of a first electronic device, and cooling liquid flow paths of the at least two liquid cooling plates are arranged in parallel so as to enable liquid cooling heat dissipation of the first electronic device; alternatively,

The at least two liquid cooling plates are arranged in a stacked manner with a second electronic device arranged between the adjacent liquid cooling plates, wherein the first heat dissipation surface of one of the adjacent liquid cooling plates is in butt joint with a first surface of the second electronic device that is planar, and a second heat dissipation surface of the other one of the adjacent liquid cooling plates is in butt joint with a second surface of the second electronic device on which heating units are arranged, wherein heat dissipation bosses on the second heat dissipation surface abut against the heating units; the cooling liquid flow paths of the at least two liquid cooling plates are arranged in parallel, so as to enable liquid cooling heat dissipation of the second electronic device.

It should be noted that in the aspect of materials, the liquid cooling plate in the above embodiment should be made of materials having good heat conduction performance and small density, such as metal or alloy materials, especially aluminum alloy materials.

It can be seen from the above embodiment that the liquid cooling plate in an embodiment of the present application is provided with a planar heat dissipation surface and a boss heat dissipation surface that are parallel to each other, and further the two liquid cooling plates may help to dissipate heat from two surfaces of the second electronic device (such as the hashboard) provided with heating units, and the liquid cooling plate is further suitable for the first electronic device such as the power box, etc. The liquid cooling plate provided in an embodiment of the present application has a good heat dissipation effect and may completely bear the heat dissipation loads of the above electronic devices, so that the heat dissipation fan is removed and the technical problems of poor heat dissipation effect and inconvenient mounting and using caused by using the fan for heat dissipation are solved. Thus, the heat dissipation requirements of two electronic devices such as the power box and the hashboard are satisfied without the fan for heat dissipation, and the technical effect of uniform heat dissipation is achieved.

The basic principles of the present application are described above in connection with particular embodiments. However, it is to be noted that the advantages, strengths, effects, etc. mentioned in the present application are merely examples and not limitations, and these advantages, strengths, effects, etc. shall not be considered as necessary for each of the embodiments of the present application. In addition, specific details disclosed above are only for examples and understanding rather than limitation, and the above details do not limit the present application to be implemented with the above specific details.

The block diagrams of components, apparatuses, devices, and systems involved in the present application are only illustrative examples, and are not intended to require or imply that connections, arrangements, and configurations must be made in the manner shown in the block diagrams. As will be recognized by those skilled in the art, these components, apparatuses, devices, and systems can be connected, arranged, and configured in any manner. Words such as “comprising”, “including”, “having”, etc. are open-ended words, which refer to “including, but not limited to” and can be used interchangeably therewith. Words “or” and “and” used herein refer to words “and/or”, and can be used interchangeably therewith, unless the context clearly dictates otherwise. The word “such as” used herein refers to the phrase “such as, but not limited to”, and can be used interchangeably therewith.

It should be further noted that in the apparatuses, devices, and methods of the present application, components or steps can be decomposed and/or recombined. Such decomposition and/or recombination should be considered equivalents of the present application.

What is described above of the disclosed aspects is provided to enable any of those skilled in the art to make or use the present application. Various modifications to these aspects will be readily apparent to those skilled in the art, and the general principles defined herein can be applied to other aspects without departing from the scope of the present application. Therefore, the present application is not intended to be limited to the aspects shown herein but is in accordance with the widest scope consistent with the principles and novel features disclosed herein.

What is described above has been provided for illustration and description. Moreover, the description is not intended to limit embodiments of the present application to the form disclosed herein. Although a number of exemplary aspects and embodiments have been discussed above, those of skill in the art will recognize that certain variations, modifications, changes, additions and sub-combinations thereof all should fall within the scope of protection of the present application.

1. A liquid cooling plate suitable for liquid cooling heat dissipation of an electronic device, wherein the liquid cooling plate comprises a liquid cooling plate body and at least one heat dissipation flow channel (133),
the liquid cooling plate body is provided with a first heat dissipation surface (131) and a second heat dissipation surface (132) that are arranged in parallel, wherein the first heat dissipation surface (131) is planar, and a plurality of heat dissipation bosses (1321) are arranged on the second heat dissipation surface (132); and
heat dissipation flow channels (133) extending along the heat dissipation bosses (1321) are provided inside the liquid cooling plate body at positions corresponding to at least one of the heat dissipation bosses (1321) between the first heat dissipation surface (131) and the second heat dissipation surface (132), wherein the plurality of heat dissipation flow channels (133) are connected to form a cooling liquid flow path having an inlet and an outlet.

2. The liquid cooling plate according to claim 1, wherein the first heat dissipation surface (131) is used for being in butt joint with a planar surface of a first electronic device (15), and a cooling liquid flows into the inlet of the cooling liquid flow path and flows out of the outlet so as to enable liquid cooling heat dissipation of the first electronic device (15); alternatively,
the first heat dissipation surface (131) is used for being in butt joint with a first surface of a second electronic device (16) that is planar, and the second heat dissipation surface (132) is used for being in butt joint with a second surface of the second electronic device (16) on which heating units (162) are arranged, wherein the heat dissipation bosses (1321) are used for abutting against the heating units (162), each of the heat dissipation bosses (1321) corresponds to at least one of the heating units in a section width perpendicular to a flow direction of the cooling liquid; the cooling liquid flows into the inlet of the cooling liquid flow path and flows out of the outlet so as to enable liquid cooling heat dissipation of the second electronic device (16).

3. The liquid cooling plate according to claim 1, wherein the plurality of heat dissipation flow channels (133) are connected in series to form the cooling liquid flow path.

4. The liquid cooling plate according to claim 3, wherein the liquid cooling plate body also has a first side wall and a second side wall that are oppositely arranged between the first heat dissipation surface (131) and the second heat dissipation surface (132); wherein the inlet and the outlet of the cooling liquid flow path are both provided on the first side wall.

5. The liquid cooling plate according to claim 4, wherein the liquid cooling plate body comprises a heat dissipation body (13) and a first sealing plate (11) and a second sealing plate (12) mounted on the heat dissipation body (13); wherein
the heat dissipation body (13) has the first heat dissipation surface (131) and the second heat dissipation surface (132), the heat dissipation flow channels (133) being arranged inside the heat dissipation body (13), the heat dissipation flow channels (133) penetrating two ends of the heat dissipation body (13),
the first sealing plate (11) and the second sealing plate (12) are mounted at the two ends of the heat dissipation body (13) respectively, so that the first sealing plate (11) and the second sealing plate (12) seal the heat dissipation flow channels (133) and the first sealing plate (11) and the second sealing plate (12) form the first side wall and the second side wall respectively; wherein a first through hole (111) and a second through hole (112) are each provided on the first sealing plate (11), and the first through hole (111) and the second through hole (112) form the inlet and the outlet of the cooling liquid flow path respectively.

6. The liquid cooling plate according to claim 5, wherein the adjacent heat dissipation flow channels (133) are separated by a supporting wall (134), on which a gap (135) is provided; moreover, the gaps (135) of the adjacent supporting walls (134) are close to the first sealing plate (11) and the second sealing plate (12) respectively, so as to connect the plurality of heat dissipation flow channels (133) in series to form the cooling liquid flow path.

7. The liquid cooling plate according to claim 1, wherein the first heat dissipation surface (131) is provided with a plurality of first mounting holes (1311) that avoid the heat dissipation flow channels (133).

8. The liquid cooling plate according to claim 7, wherein a mounting outer edge (1312) protrudes from the first heat dissipation surface (131) and is provided with a second mounting hole (1313).

9. The liquid cooling plate according to claim 1, wherein the second heat dissipation surface (132) is further provided with abutment bosses (1322) higher than the heat dissipation bosses (1321), so as to make the abutment bosses (1322) abut against the second surface of the second electronic device (16) while the heat dissipation bosses (1321) abutting against the heating units (162).

10. The liquid cooling plate according to claim 9, wherein the abutment bosses (1322) are arranged at two ends of the second heat dissipation surface (132), and/or the abutment bosses (1322) are arranged between the adjacent heat dissipation bosses (1321).

11. The liquid cooling plate according to claim 1, wherein the first heat dissipation surface (131) is coated with thermally conductive silicone grease, and surfaces of the heat dissipation bosses are provided with thermally conductive silicone pads.

12. The liquid cooling plate according to claim 1, wherein inner walls of the heat dissipation flow channels (133) are provided with flow disturbing structures.

13. The liquid cooling plate according to claim 12, wherein the flow disturbing structures comprise corrugated protrusions (1331) or tooth-shaped protrusions extending along the heat dissipation flow channel, and/or the flow disturbing structures comprise spiral protrusions extending along the heat dissipation flow channel.

14. The liquid cooling plate according to claim 1, wherein the first through hole (111) and the second through hole (112) extend outwards to be provided with butt joint pipes (14) used to be connected to the cooling liquid.

15. The liquid cooling plate according to claim 1, wherein the plurality of the heat dissipation flow channels (133) are connected in parallel to form the cooling liquid flow path.

16. A heat dissipation unit, wherein the heat dissipation unit comprises at least two liquid cooling plates of claim 1;
wherein the first heat dissipation surfaces (131) of the at least two liquid cooling plates are in butt joint with a planer surface of a first electronic device (15), and cooling liquid flow paths of the at least two liquid cooling plates are arranged in parallel so as to enable liquid cooling heat dissipation of the first electronic device (15); alternatively,
the at least two liquid cooling plates are arranged in a stacked manner, and a second electronic device (16) is arranged between the adjacent liquid cooling plates, wherein the first heat dissipation surface (131) of one of the adjacent liquid cooling plates is in butt joint with a first surface of the second electronic device (16) that is planar, and a second heat dissipation surface (132) of the other one of the adjacent liquid cooling plates is in butt joint with a second surface of the second electronic device (16) on which heating units (162) are arranged, wherein heat dissipation bosses (1321) on the second heat dissipation surface (132) abut against the heating units (162); the cooling liquid flow paths of the at least two liquid cooling plates are arranged in parallel so as to enable liquid cooling heat dissipation of the second electronic device (16).
